(19) United States
(12) Patent Application Publication
(10) Pub. No.: US 2021/0044297 A1
(43) Pub. Date: Feb. 11, 2021

(54) IMAGE SENSOR

(71) Applicant: SAMSUNG ELECTRONICS CO., LTD., Suwon-si (KR)

(72) Inventors: Jae Seung Han, Hwaseong-si (KR); Yun Hwan Jung, Hwaseong-si (KR); Jae Young Bae, Seoul (KR); Suk Ki Yoon, Suwon-si (KR)

(73) Assignee: SAMSUNG ELECTRONICS CO., LTD., Suwon-si (KR)

(21) Appl. No.: 16/819,666

(22) Filed: Mar. 16, 2020

(30) Foreign Application Priority Data
Aug. 5, 2019 (KR) 10-2019-0094883

(51) Int. Cl. H03K 19/0185; G11C 16/12; H03K 3/356; H03K 19/003

(52) U.S. Cl. CPC H03K 19/018521; G11C 16/12; H03K 19/00315; H03K 3/35613; H03K 3/356182

(57) ABSTRACT

An image sensor includes a shifting circuit shifting a first voltage that is applied to a first node, to a second voltage, and shifting the second voltage that is applied to a second node, to the first voltage, and a sub-circuit providing the first voltage to the shifting circuit. The image sensor further includes a source circuit enabling the sub-circuit to provide the first voltage to the shifting circuit, and an enable transistor that is gated by an enable signal, and enables the shifting circuit by providing the second voltage to the shifting circuit, based on the enable signal.

### CROSS-REFERENCE TO THE RELATED APPLICATION

This application is based on and claims priority under 35 U.S.C. § 119 of Korean Patent Application No. 10-2019-0094883, filed on Aug. 5, 2019, in the Korean Intellectual Property Office, the disclosure of which is incorporated by reference herein in its entirety.

### BACKGROUND

### 1. Field

The disclosure relates to an image sensor.

### 2. Description of the Related Art

Image sensors are semiconductor elements that convert optical information into electrical signals. Examples of image sensors include a charge-coupled device (CCD) image sensor and a complementary metal-oxide semiconductor (CMOS) image sensor.

Level shifters for shifting an input voltage into a voltage for driving are used in image sensors.

### SUMMARY

According to embodiments, an image sensor includes a shifting circuit shifting a first voltage that is applied to a first node, to a second voltage, and shifting the second voltage that is applied to a second node, to the first voltage, and a sub-circuit providing the first voltage to the shifting circuit. The image sensor further includes a source circuit enabling the sub-circuit to provide the first voltage to the shifting circuit, and an enable transistor that is gated by an enable signal, and enables the shifting circuit by providing the second voltage to the shifting circuit, based on the enable signal.

According to embodiments, an image sensor includes a first circuit shifting a voltage of a first node from a first voltage to a second voltage, using three first transistors, and a second circuit shifting a voltage of a second node from the second voltage to the first voltage, using three second transistors, the voltage of the second node being different from the voltage of the first node. The image sensor further includes an enable transistor that is gated by an enable signal, and enables the first circuit and the second circuit by pulling down either one or both of the voltage of the first node and the voltage of the second node, to the second voltage, based on the enable signal. Two of the three first transistors are gated by the voltage of the second node, and two of the three second transistors are gated by the voltage of the first node.

According to embodiments, an image sensor includes a pixel array including one or more pixels, and a row driver outputting a control signal for controlling an operation of the one or more pixels. The image sensor further includes an analog-to-digital converter converting a pixel signal that is output from the one or more pixels via a column line, into a digital signal, and outputting the digital signal, and a timing generator generating a clock signal, and transmitting the clock signal to the row driver and the analog-to-digital converter. The row driver includes a shifting circuit including two inverters that are cross-coupled and output a target voltage, and a source circuit including a current source that is connected to a source node, and a source transistor that is gated by a voltage of the source node. The row driver further includes a sub-circuit that is gated by the voltage of the source node, and provides the target voltage to the shifting circuit, based on the voltage of the source node, and an enable circuit receiving an enable signal, and enables the shifting circuit based on the enable signal.

### BRIEF DESCRIPTION OF THE DRAWINGS

FIG. 1 is a block diagram of an image sensor according to embodiments.

FIG. 2 is a block diagram of a row driver according to embodiments.

FIG. 3 is a circuit diagram of a level shifter included in the row driver of FIG. 2.

FIG. 4 is a circuit diagram of another example of a level shifter included in the row driver of FIG. 2.

FIG. 5 is a graph showing a variation of voltages of FIG. 3.

FIG. 6 is a timing diagram illustrating an operation of the level shifter of FIG. 3.

FIGS. 7 and 8 are circuit diagrams illustrating operations of the level shifter of FIG. 3.

FIG. 9 is a circuit diagram of a level shifter included in an image sensor according to embodiments.

FIG. 10 is a circuit diagram of another example of a level shifter included in an image sensor according to embodiments.

FIG. 11 is a graph showing a variation of voltages of FIG. 10.

FIG. 12 is a circuit diagram of still another example of a level shifter included in an image sensor according to embodiments.

FIG. 13 is a timing diagram illustrating an operation of the level shifter of FIG. 12.

FIGS. 14 and 15 are circuit diagrams illustrating operations of the level shifter of FIG. 12.

### DETAILED DESCRIPTION

Embodiments provide an image sensor capable of reducing a size of an entire row driver by reducing a size of level shifters included in the row driver. The image sensor is also capable of improving reliability by reducing signal delays between input and output.

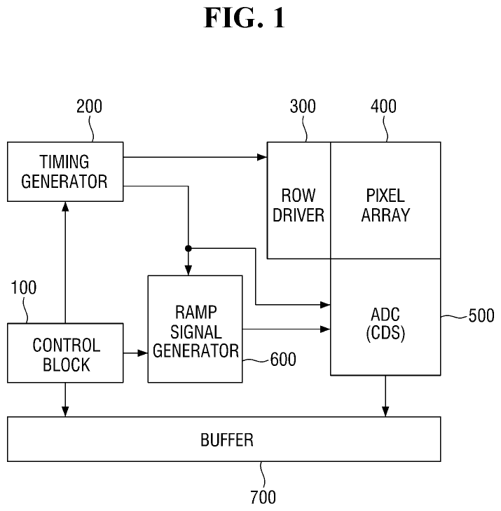

FIG. 1 is a block diagram of an image sensor according to embodiments.

Referring to FIG. 1, the image sensor may include a control block 100, a timing generator 200, a row driver 300, a pixel array 400, an analog-to-digital converter (ADC) 500, a ramp signal generator 600, and a buffer 700.

The control block 100 may control the operation of the image sensor. The control block 100 may transmit operation signals directly to the timing generator 200, the ramp signal generator 600, and the buffer 700.

The timing generator 200 may generate an operational timing reference signal that is a reference signal for the operational timings of various elements of the image sensor. The operational timing reference signal may be transmitted to the row driver, 300, the ADC 500, and the ramp signal generator 600.

The pixel array 400 may sense an external image. The pixel array 400 may include a plurality of pixels (or unit pixels). The row driver 300 may selectively activate rows of pixels of the pixel array 400.

The ADC 500 may sample a pixel signal provided by the pixel array 400, may compare the sampled pixel signal with a ramp signal, and may convert analog image data into digital image data based on the result of the comparison.

The ADC 500 is illustrated as including a correlated double sampler (CDS), a comparator, but the embodiments are not limited thereto. The CDS, the comparator, and the like may be implemented as separate logic circuits from the ADC 500.

The ramp signal generator 600 may generate and transmit a ramp signal for use in the ADC 500. For example, the ADC 500 may include a CDS, a comparator, and the like, and the ramp signal generator 600 may generate and transmit a ramp signal for use in the CDS, the comparator, and the like of the ADC 500.

The buffer 700 may include, for example, a latch. The buffer 700 may temporarily store an image signal to be provided to the outside of the image sensor and may transmit image data to an external memory or an external device.

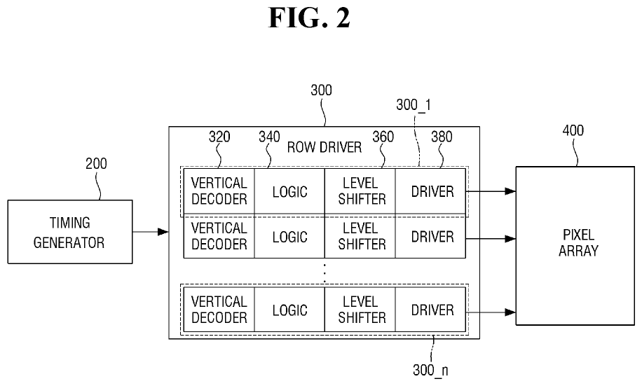

FIG. 2 is a block diagram of a row driver according to embodiments.

Referring to FIG. 2, a row driver 300 may include a plurality of row driver unit 300_1 to 300_n. Each of the row driver units 300_1 to 300_n may include a vertical decoder 320, a logic unit 340, a level shifter 360, and a driver 380.

Each of the row driver units 300_1 to 300_n may receive an operational timing reference signal generated by a timing generator 200.

The logic unit 340 may provide enable signals to the level shifter 360 in accordance with the result of decoding performed by the vertical decoder 320.

The level shifter 360 may be enabled by the enable signals to output voltages.

The level shifter 360 may include a shifting circuit, in which two inverters are cross-coupled to output a target voltage, a source circuit, a sub-circuit, and an enable circuit.

In the shifting circuit, two inverters may be cross-coupled to output the target voltage. The source circuit may include a current source that is connected to a source node and a source transistor that is gated by the source node. The sub-circuit may be gated by the voltage of the source node to provide the target voltage to the shifting circuit. The enable circuit may receive an enable signal to enable the shifting circuit.

The drivers 380 may correct the voltages output by the level shifters 360 and may input the corrected voltages to a pixel array 400.

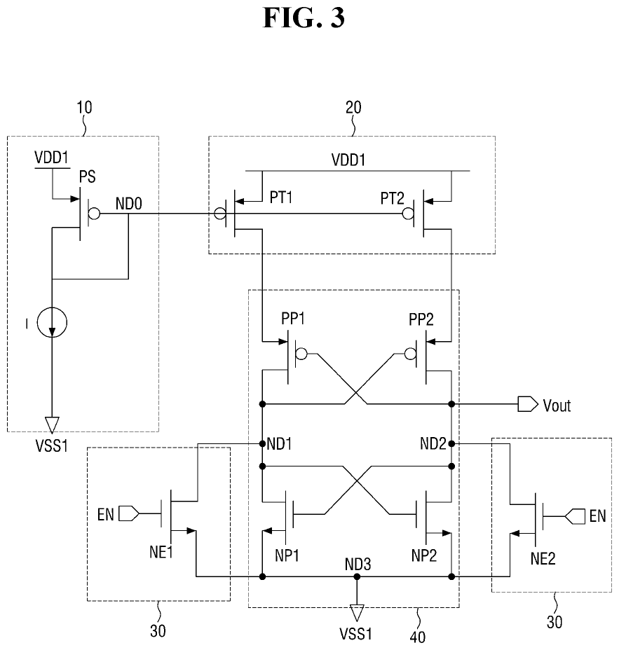

FIG. 3 is a circuit diagram of a level shifter included in the row driver of FIG. 2.

Referring to FIG. 3, a level shifter may include a source circuit 10, a sub-circuit 20, an enable circuit 30, and a shifting circuit 40.

The source circuit 10 may include a current source I, which is connected to a source node ND0, and a source transistor PS.

The source transistor PS may be implemented as, for example, a P-type metal-oxide semiconductor (PMOS) transistor.

A gate terminal of the source transistor PS may be gated by the voltage of the source node ND0, a first terminal of the source transistor PS may be connected to a first voltage VDD1, and a second terminal of the source transistor PS may be connected to the current source I.

The source transistor PS may be gated by the voltage of the source node ND0 and may provide the first voltage VDD1 to the source node ND0.

The first voltage VDD1 may be a target voltage to be output by the level shifter.

The current source I may be connected to the source node ND0.

That is, the current source I and a second terminal of the source transistor PS may be connected to the source node ND0. Accordingly, the voltage of the source node ND0 may be between the first voltage VDD1 and a second voltage VSS1, which bias first and second transistors PT1 and PT2.

A single sub-circuit 20 is illustrated as being connected to the source circuit 10, but the embodiments are not limited thereto. That is, alternatively, multiple sub-circuits 20 may be connected to the source circuit 10.

The sub-circuit 20 may be enabled by the source circuit 10, which includes the source node ND0.

The sub-circuit 20 may include the first and second transistors PT1 and PT2.

The first and second transistors PT1 and PT2 may be implemented as, for example, PMOS transistors.

A gate terminal of the first transistor PT1 may be gated by the voltage of the source node ND0, a first terminal of the first transistor PT1 may be connected to the first voltage VDD1, and a second terminal of the first transistor PT1 may be connected to a first pull-up transistor PP1, which will be described later.

The first transistor PT1 may be gated by the voltage of the source node ND0 to provide the first voltage VDD1 to the first pull-up transistor PP 1.

A gate terminal of the second transistor PT2 may be gated by the voltage of the source node ND0, a first terminal of the second transistor PT2 may be connected to the first voltage VDD1, and a second terminal of the second transistor PT2 may be connected to a second pull-up transistor PP2, which will be described later.

The second transistor PT2 may be gated by the voltage of the source node ND0 to provide the first voltage VDD1 to the second pull-up transistor PP2.

The shifting circuit 40 may include first and second nodes ND1 and ND2 and may shift the voltage of the first node ND1 to the voltage of the second node ND2, and may shift the voltage of the second node ND2 to the voltage of the first node ND1.

The shifting circuit 40 may further include the first pull-up transistor PP1, the second pull-up transistor PP2, a first pull-down transistor NP1, and a second pull-down transistor NP2.

The first and second pull-up transistors PP1 and PP2 may be implemented as, for example, PMOS transistors.

A gate terminal of the first pull-up transistor PP1 may be gated by the voltage of the second node ND2, a first terminal of the first pull-up transistor PP1 may be connected to the first transistor PT1, and a second terminal of the first pull-up transistor PP1 may be connected to the first node ND1.

The first pull-up transistor PP1 may be gated by the voltage of the second node ND2 to provide the first voltage VDD1 to the first node ND1.

A gate terminal of the second pull-up transistor PP2 may be gated by the voltage of the first node ND1, a first terminal of the second pull-up transistor PP2 may be connected to the second transistor PT2, and a second terminal of the second pull-up transistor PP2 may be connected to the second node ND2.

The second pull-up transistor PP2 may be gated by the voltage of the first node ND1 to provide the first voltage VDD1 to the second node ND2.

The first and second pull-down transistors NP1 and NP2 may be implemented as, for example, N-type metal-oxide semiconductor (NMOS) transistors.

A gate terminal of the first pull-down transistor NP1 may be gated by the voltage of the second node ND2, a first terminal of the first pull-down transistor NP1 may be connected to the first node ND1, and a second terminal of the first pull-down transistor NP1 may be connected to a third node ND3.

The first pull-down transistor NP1 may be gated by the voltage of the second node ND2 to provide the second voltage VSS1 to the first node ND1.

A gate terminal of the second pull-down transistor NP2 may be gated by the voltage of the first node ND1, a first terminal of the second pull-down transistor NP2 may be connected to the second node ND2, and a second terminal of the second pull-down transistor NP2 may be connected to the third node ND3.

The second pull-down transistor NP2 may be gated by the voltage of the first node ND1 to provide the second voltage VSS1 to the second node ND2.

The second voltage VSS1 may include, for example, a ground voltage, but the embodiments are not limited thereto.

The first pull-up transistor PP1 and the first pull-down transistor NP1 are gated by the voltage of the second node ND2, and the second pull-up transistor PP2 and the second pull-down transistor NP2 are gated by the voltage of the first node ND1. Thus, in response to the first pull-up transistor PP1 and the second pull-up transistor PP2 being turned on, the first pull-down transistor NP2 and the second pull-down transistor NP2 may be turned off.

Also, in response to the first pull-up transistor PP1 and the second pull-up transistor PP2 being turned on, the second pull-down transistor NP2 and the first pull-down transistor NP1 may be turned on.

That is, the shifting circuit 40 may include a structure in which two inverters are cross-coupled.

The enable circuit 30 receives an enable signal EN having a first logic level H to provide the second voltage VSS1 to the first node ND1 and to enable the shifting circuit 40.

The enable signal EN may include, for example, an input voltage Vin which is input to the enable circuit 30.

The enable circuit 30 may include first and second enable transistors NE1 and NE2.

The enable circuit 30 is illustrated as including both the first and second enable transistors NE1 and NE2, but the embodiments are not limited thereto. That is, the configuration of the enable circuit 30 may vary. For example, the enable circuit 30 may include either one or both of the first and second enable transistors NE1 and NE2.

The first and second enable transistors NE1 and NE2 may be implemented as, for example, NMOS transistors.

The first enable transistor NE1 may be gated by the enable signal EN to provide the second voltage VSS1 to the first node ND1. A gate terminal of the first enable transistor NE1 may receive the enable signal EN, a first terminal of the first enable transistor NE1 may be connected to the first node ND1, and a second terminal of the first enable transistor NE1 may be connected to the third node ND3.

The second enable transistor NE2 may be gated by the enable signal EN to provide the second voltage VSS1 to the second node ND2. A gate terminal of the second enable transistor NE2 may receive the enable signal EN, a first terminal of the second enable transistor NE2 may be connected to the second node ND2, and a second terminal of the second enable transistor NE2 may be connected to the third node ND3.

The voltage shifted by the shifting circuit 40 may be output from the second node ND2 as an output voltage Vout.

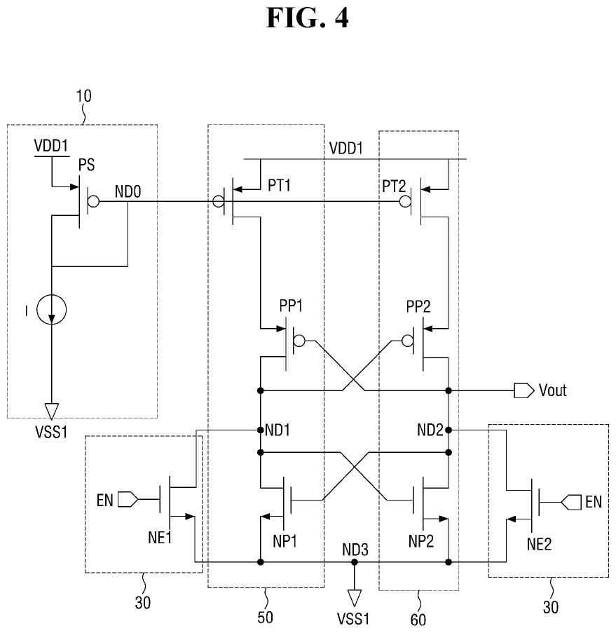

FIG. 4 is a circuit diagram of another example of a level shifter included in the row driver of FIG. 2.

FIG. 4 illustrates a level shifter as circuitry including a source circuit 10, an enable circuit 30, a first circuit 50, and a second circuit 60. For convenience, the level shifter of FIG. 4 will hereinafter be described, focusing mainly on the differences with the level shifter of FIG. 3.

The first circuit 50 may include a first transistor PT1, a first pull-up transistor PP1, and a first pull-down transistor NP1.

The first transistor PT1 may provide a first voltage VDD1 to the first pull-up transistor PP1.

The first pull-up transistor PP1 may provide the first voltage VDD1 to a first node ND1. The first pull-up transistor PP1 may pull up the voltage of the first node ND1.

The first pull-down transistor NP1 may provide a second voltage VSS1 to the first node ND1. The first pull-down transistor NP1 may pull down the voltage of the first node ND1.

The second circuit 60 may include a second transistor PT2, a second pull-up transistor PP2, and a second pull-down transistor NP2.

The second transistor PT2 may provide the first voltage VDD1 to the second pull-up transistor PP2.

The second pull-up transistor PP2 may provide the first voltage VDD1 to a second node ND2. The second pull-up transistor PP2 may pull up the voltage of the second node ND2.

The second pull-down transistor NP2 may provide the second voltage VSS1 to the second node ND2. The second pull-down transistor NP2 may pull down the voltage of the second node ND2.

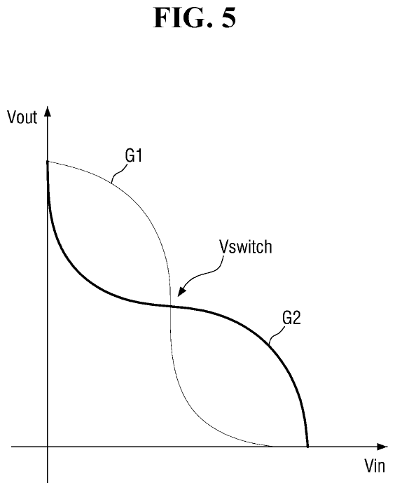

FIG. 5 is a graph showing a variation of voltages of FIG. 3.

Referring to FIGS. 3 to 5, a first graph G1 may indicate the voltage of the first node ND1, and a second graph G2 may indicate the voltage of the second node ND2.

Alternatively, the first graph G1 may indicate the voltage of the second node ND2 of FIG. 3, and the second graph G2 may indicate the voltage of the first node ND1.

A switch voltage Vswitch may be the voltage at the intersection between the first and second graphs G1 and G2. The switch voltage Vswitch may be the voltage at the time when the voltage of the first node ND1 and the voltage of the second node ND2 become identical.

If one of the voltages of the first and second nodes ND1 and ND2 reaches the switch voltage Vswitch, the voltages of the first and second nodes ND1 and ND2 may diverge from each other.

Thus, if one of the voltages of the first and second nodes ND1 and ND2 increases, the other voltage may decrease.

Also, because the voltage of the second node ND2 is quickly developed to the switch voltage Vswitch, a delay in the output of the output voltage Vout after the application of the enable signal EN can be reduced.

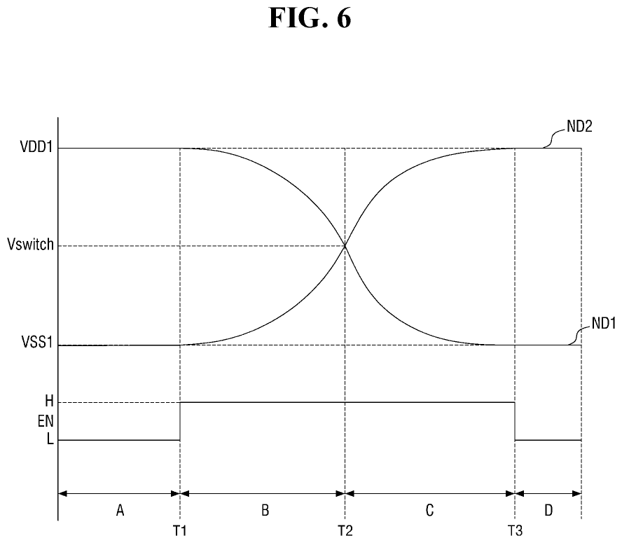

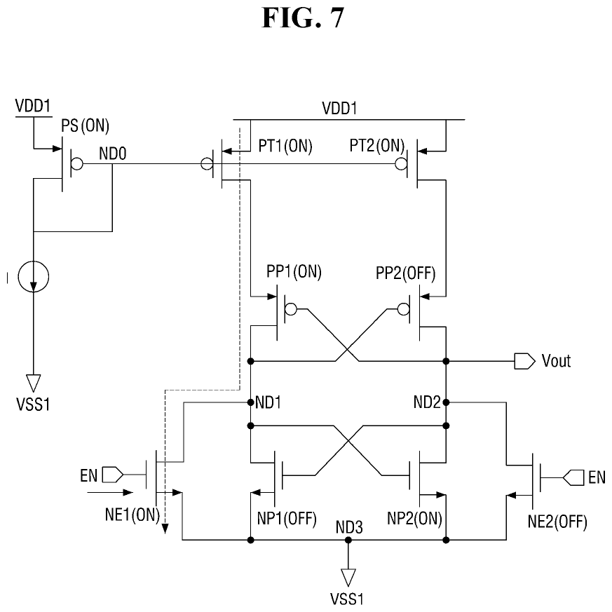

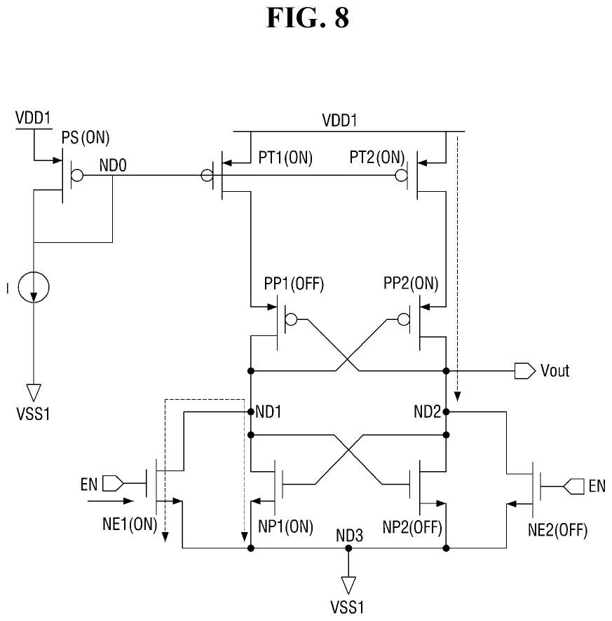

FIG. 6 is a timing diagram illustrating an operation of the level shifter of FIG. 3. FIGS. 7 and 8 are circuit diagrams illustrating operations of the level shifter of FIG. 3.

An operation of the level shifter of FIG. 3 will hereinafter be described with reference to FIGS. 3 through 8. For convenience, it is assumed that the enable signal EN is applied to the first enable transistor NE1, but the embodiments are not limited thereto. Alternatively, the enable signal EN may be applied to the second enable transistor NE2.

FIG. 6 illustrates the waveform of the enable signal applied to the level shifter of FIG. 3 and the variation of the voltage of each node of the level shifter of FIG. 3. The enable signal of FIG. 6 may be provided by the logic unit 340 of FIG. 2.

Referring to FIGS. 3 and 6, in a period A, the first voltage VDD1 is provided to the first node ND1, and the second voltage VSS1 is provided to the second node ND2.

Accordingly, the second pull-up transistor PP2, which is gated by the first node ND1, is turned off, and the second pull-down transistor NP2 is turned on. The first pull-up transistor PP1, which is gated by the second node ND2, is turned on, and the first pull-down transistor NP1 is turned off.

Thereafter, referring to FIGS. 6 and 7, at a first time T1, the enable signal EN is switched from a second logic level L to the first logic level H. That is, the enable signal EN may be enabled.

As a result, the first enable transistor NE1 may be turned on to provide the second voltage VSS1 to the first node ND1. Accordingly, the voltage of the first node ND1 may be developed to the switch voltage Vswitch.

The voltage of the second node ND2 may be developed to the switch voltage Vswitch, using the first voltage VDD1.

Thereafter, referring to FIGS. 6 and 8, at a second time T2, the first and second nodes ND1 and ND2 may have the switch voltage Vswitch.

Thus, in a period C, the second pull-up transistor PP2 and the first pull-down transistor NP1 are turned on, and the first pull-up transistor PP1 and the second pull-down transistor NP2 are turned off.

Accordingly, the second pull-up transistor PP2 may provide the first voltage VDD1 to the second node ND2. As a result, the voltage of the second node ND2 may be developed to the first voltage VDD1.

The first pull-down transistor NP1 may provide the second voltage VSS1 to the first node ND1. As a result, the voltage of the first node ND1 may be developed to the second voltage VSS1.

At a third time T3, if the voltage of the first node ND1 is shifted to the second voltage VSS1 and the voltage of the second node ND2 is shifted to the first voltage VDD1, the voltage of the second node ND2 may be output as the output voltage Vout.

That is, the level shifter may up-shift the voltage of the second node ND2 from the second voltage VSS1 to the first voltage VDD1.

The level shifter may be implemented as a single stage circuit, and thus, the area of the level shifter in the row driver 300 can be reduced.

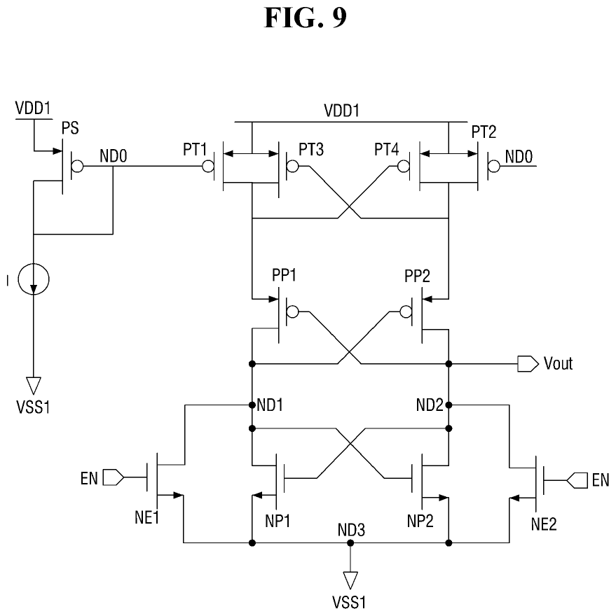

FIG. 9 is a circuit diagram of a level shifter included in an image sensor according to embodiments. For convenience, a level shifter of FIG. 9 will hereinafter be described, focusing mainly on the differences with the level shifter of FIG. 3.

Referring to FIG. 9, a sub-circuit 20 of the level shifter may further include third and fourth transistors PT3 and PT4.

The third and fourth transistors PT3 and PT4 may be implemented as, for example, PMOS transistors.

The third transistor PT3 may be gated by the output of a second pull-up transistor PP2, a first terminal of the third transistor PT3 may be connected to a first voltage VDD1, and a second terminal of the third transistor PT3 may be connected to a first pull-up transistor PP1.

The fourth transistor PT4 may be gated by the output of a first transistor PT1, a first terminal of the fourth transistor PT4 may be connected to the first voltage VDD1, and a second terminal of the fourth transistor PT4 may be connected to the second pull-up transistor PP2.

In a case in which an enable signal EN has a second logic level L, the first transistor PT1 and a second transistor PT2 are turned on. Thus, the third transistor PT3 may be gated by the output of the second transistor PT2 to be turned off, and the fourth transistor PT4 may be gated by the output of the first transistor PT1 to be turned off.

In a case in which the enable signal EN has a first logic level H, a first enable transistor NE1 may be gated to provide a second voltage VSS1 to a first node ND1, and the fourth transistor PT4 may be gated by the voltage of the first node ND1, provided via the first pull-up transistor PP1, to provide the first voltage VDD1 to the second pull-up transistor PP2.

Accordingly, the voltages of the first and second nodes ND1 and ND2 can be quickly developed to the switch voltage Vswitch.

The level shifter is illustrated as including both the first and second enable transistors NE1 and NE2, but the embodiments are not limited thereto. That is, the structure of the level shifter of FIG. 9 may vary. For example, an enable circuit 30 may include either one or both of the first and second enable transistors NE1 and NE2.

The first and second enable transistors NE1 and NE2 of the level shifter may be gated by the enable signal EN.

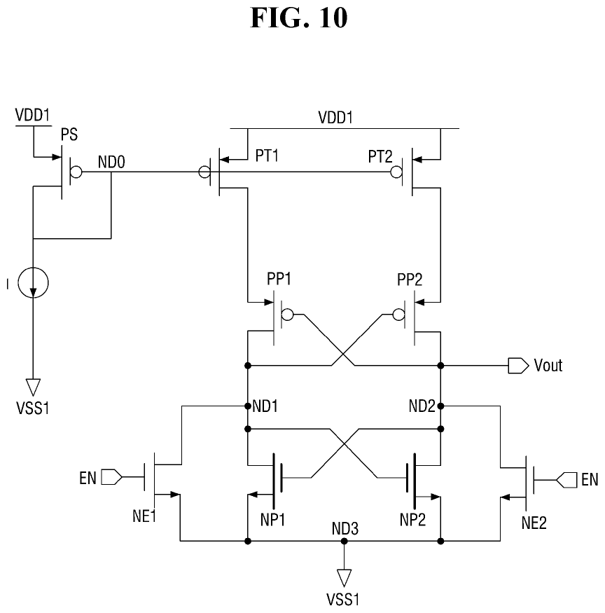

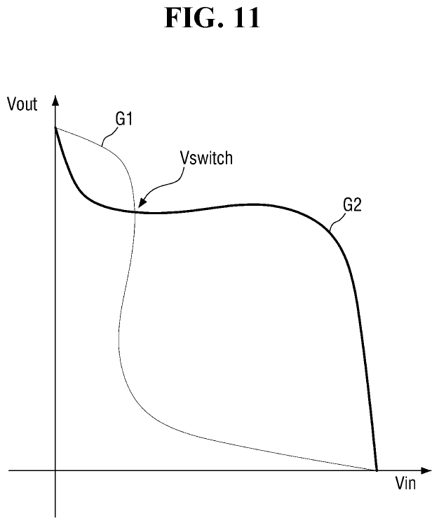

FIG. 10 is a circuit diagram of another example of a level shifter included in an image sensor according to embodiments. FIG. 11 is a graph showing a variation of voltages of FIG. 10.

Referring to FIG. 10, first and second pull-down transistors NP1 and NP2 (bolded in FIG. 10) may have a different length or width from other transistors (PS, PT1, PT2, PP1, PP2, NE1, and NE2). The width-to-length ratio (L/W) of the first and second pull-down transistors NP1 and NP2 may be greater than the width-to-length ratio of the other transistors (PS, PT1, PT2, PP1, PP2, NE1, and NE2).

Referring to FIG. 11, a switch voltage Vswitch may be determined by either one or both of the length and width of the first and second pull-down transistors NP1 and NP2, or first and second pull-up transistors PP1 and PP2. That is, as the width-to-length ratio (L/W) of the first and second pull-down transistors NP1 and NP2, or the first and second pull-up transistors PP1 and PP2 increases, the switch voltage Vswitch may also increase.

Accordingly, the voltages of first and second nodes ND1 and ND2 can be quickly developed to the switch voltage Vswitch, and the voltage of the second node ND2 can be quickly developed to a first voltage VDD1.

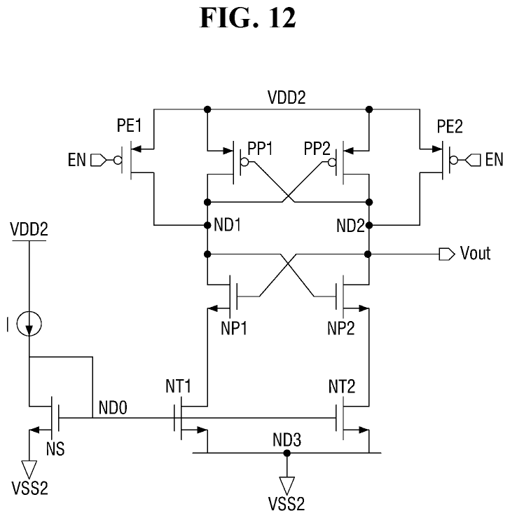

FIG. 12 is a circuit diagram of still another example of a level shifter included in an image sensor according to embodiments. A level shifter of FIG. 12 will hereinafter be described, focusing mainly on the differences with the level shifter of FIG. 3.

Referring to FIG. 12, first and second enable transistors PE1 and PE2 may be implemented as PMOS transistors.

A source transistor NS, a first transistor NT1, and a second transistor NT2 may be implemented as NMOS transistors.

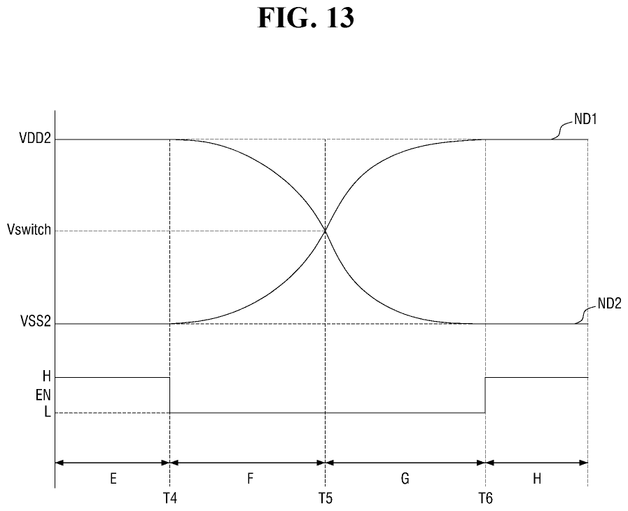

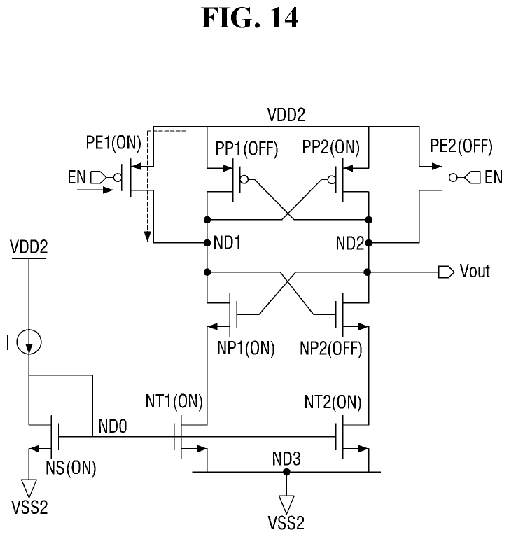

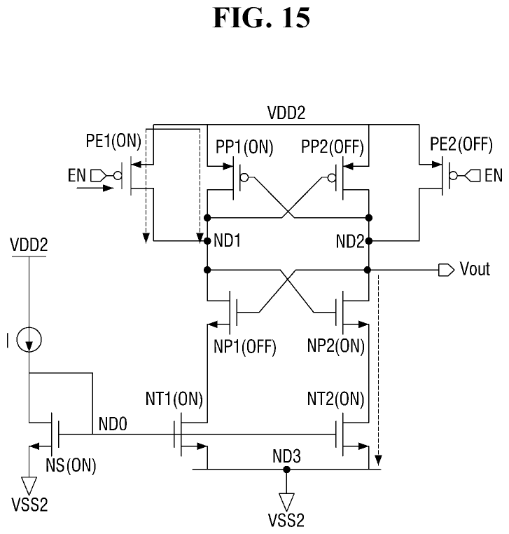

FIG. 13 is a timing diagram illustrating an operation of the level shifter of FIG. 12. FIGS. 14 and 15 are circuit diagrams illustrating operations of the level shifter of FIG. 12.

An operation of the level shifter of FIG. 12 will hereinafter be described with reference to FIGS. 12 through 15. For convenience, it is assumed that an enable signal EN is applied to a first enable transistor PE1, but the embodiments are not limited thereto. Alternatively, the enable signal EN may be applied to a second enable transistor PE2.

Referring to FIGS. 12 and 13, in a period E, a second voltage VSS2 is provided to a first node ND1, and a first voltage VDD2 is provided to a second node ND2.

Accordingly, a second pull-up transistor PP2, which is gated by the first node ND1, is turned on, and a second pull-down transistor NP2 is turned on. A first pull-up transistor PP1, which is gated by the second node ND2, is turned off, and a first pull-down transistor NP1 is turned on.

Thereafter, referring to FIGS. 13 and 14, at a fourth time T4, the enable signal EN is switched from a first logic level H to a second logic level L. That is, the enable signal EN may be enabled.

As a result, the first enable transistor PE1 may be turned on to provide the first voltage VDD2 to the first node ND1. Accordingly, the voltage of the first node ND1 may be developed to a switch voltage Vswitch.

The voltage of the second node ND2 may be developed to the switch voltage Vswitch, using the second voltage VSS2.

Thereafter, referring to FIGS. 13 and 15, at a fifth time T5, the first and second nodes ND1 and ND2 may have the switch voltage Vswitch.

Thus, in a period G, the second pull-up transistor PP2 and the first pull-down transistor NP1 are turned off, and the first pull-up transistor PP1 and the second pull-down transistor NP2 are turned on.

Accordingly, the second pull-down transistor NP2 may provide the second voltage VSS2 to the second node ND2. As a result, the voltage of the second node ND2 may be developed to the second voltage VSS2.

The first pull-up transistor PP1 may provide the first voltage VDD2 to the first node ND1. As a result, the voltage of the first node ND1 may be developed to the first voltage VDD2.

At a sixth time T6, if the voltage of the first node ND1 is shifted to the first voltage VDD2 and the voltage of the second node ND2 is shifted to the second voltage VSS2, the voltage of the second node ND2 may be output as an output voltage Vout.

That is, the level shifter may down-shift the voltage of the second node ND2 from the second voltage VSS2 to the first voltage VDD2. The level shifters have been described as being included in an image sensor, but the embodiments are not limited thereto. That is, the level shifters can be included in a sensor to up-shift the level of a digital signal. The level shifters can be applied to, for example, a display driver integrated circuit (IC) for driving a display.

As is traditional in the field of the technical concepts, the embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions. Also, each block, unit and/or module of the embodiments may be physically separated into two or more interacting and discrete blocks, units and/or modules without departing from the scope of the technical concepts. Further, the blocks, units and/or modules of the embodiments may be physically combined into more complex blocks, units and/or modules without departing from the scope of the technical concepts.

In concluding the detailed description, those skilled in the art will appreciate that many variations and modifications may be made to the embodiments without substantially departing from the principles of the present technical concept. Therefore, the embodiments of the technical concept are used in a generic and descriptive sense only and not for purposes of limitation.

The embodiments of the present technical concept have been described with reference to the attached drawings, but it may be understood by one of ordinary skill in the art that the present technical concept may be performed one of ordinary skill in the art in other forms without changing the technical concept or features of the present technical concept. Further, the above-described embodiments are examples and do not limit the scope of the rights of the present technical concept.

What is claimed is:

1. An image sensor comprising:
a shifting circuit shifting a first voltage that is applied to a first node, to a second voltage, and shifting the second voltage that is applied to a second node, to the first voltage;
a sub-circuit providing the first voltage to the shifting circuit;
a source circuit enabling the sub-circuit to provide the first voltage to the shifting circuit; and
an enable transistor that is gated by an enable signal, and enables the shifting circuit by providing the second voltage to the shifting circuit, based on the enable signal.

2. The image sensor of claim 1, wherein the shifting circuit comprises:
a first pull-up transistor that is gated by a voltage of the second node, and provides the first voltage to the first node, based on the voltage of the second node;
a second pull-up transistor that is gated by a voltage of the first node, and provides the first voltage to the second node, based on the voltage of the first node;
a first pull-down transistor that is gated by the voltage of the second node, and provides the second voltage to the first node, based on the voltage of the second node; and
a second pull-down transistor that is gated by the voltage of the first node, and provides the second voltage to the second node, based on the voltage of the first node.

3. The image sensor of claim 2, wherein, based on the voltage of the first node being between the first voltage and a switch voltage between the first voltage and the second voltage, the first pull-up transistor and the second pull-down transistor are turned on to develop the voltage of the first node to the switch voltage, and
wherein, based on the voltage of the first node being between the switch voltage and the second voltage, the second pull-up transistor and the first pull-down transistor are turned on to develop the voltage of the first node to the second voltage.

4. The image sensor of claim 3, wherein, based on the voltage of the second node being between the second voltage and the switch voltage, the first pull-up transistor and the second pull-down transistor are turned on to develop the voltage of the second node to the switch voltage, and
wherein, based on the voltage of the second node being between the switch voltage and the first voltage, the second pull-up transistor and the first pull-down transistor are turned on to develop the voltage of the second node to the first voltage.

5. The image sensor of claim 3, wherein the switch voltage corresponds to a length or a width of each of the first pull-down transistor and the second pull-down transistor and/or a length or a width of each of the first pull-up transistor and the second pull-up transistor.

6. The image sensor of claim 2, wherein the source circuit comprises:
a current source that is connected to a source node; and
a source transistor that is connected to the source node, and is gated by a voltage of the current source.

7. The image sensor of claim 6, wherein the sub-circuit comprises:
a first transistor that is gated by the voltage of the source node, and provides the first voltage to the first pull-up transistor, based on the voltage of the source node; and
a second transistor that is gated by the voltage of the source node, and provides the first voltage to the second pull-up transistor, based on the voltage of the source node.

8. The image sensor of claim 7, wherein the sub-circuit further comprises:
a third transistor that is connected in parallel to the first pull-up transistor, and is gated by an output of the second transistor; and
a fourth transistor that is connected in parallel to the second pull-up transistor, and is gated by an output of the first transistor.

9. The image sensor of claim 1, wherein the enable transistor comprises:
a first enable transistor providing the second voltage to the first node; and
a second enable transistor providing the second voltage to the second node.

10. The image sensor of claim 9, wherein only one of the first enable transistor and the second enable transistor is gated by the enable signal.

11. An image sensor comprising:
a first circuit shifting a voltage of a first node from a first voltage to a second voltage, using three first transistors;
a second circuit shifting a voltage of a second node from the second voltage to the first voltage, using three second transistors, the voltage of the second node being different from the voltage of the first node; and
an enable transistor that is gated by an enable signal, and enables the first circuit and the second circuit by pulling down either one or both of the voltage of the first node and the voltage of the second node, to the second voltage, based on the enable signal,
wherein two of the three first transistors are gated by the voltage of the second node, and
two of the three second transistors are gated by the voltage of the first node.

12. The image sensor of claim 11, further comprising:
a current source that is connected to a source node; and
a source transistor that is gated by a voltage of the source node,
wherein one of the three first transistors that is different from the two of the three first transistors is gated by the voltage of the source node, and
wherein one of the three second transistors that is different from the two of the three second transistors is gated by the voltage of the source node.

13. The image sensor of claim 12, wherein the first circuit comprises:
a first transistor that is gated by the voltage of the source node, and provides the first voltage to the first node, based on the voltage of the source node;
a first pull-up transistor that is gated by the voltage of the second node, and is connected to the first transistor and the first node; and
a first pull-down transistor that is gated by the voltage of the second node, is connected to the first pull-up transistor, and pulls down the voltage of the first node, based on the voltage of the second node.

14. The image sensor of claim 13, wherein a size of the first pull-down transistor is different from a size of the first pull-up transistor.

15. The image sensor of claim 13, wherein the second circuit comprises:
a second transistor that is gated by the voltage of the source node, and provides the first voltage to the second node, based on the voltage of the source node;
a second pull-up transistor that is gated by the voltage of the first node, and is connected to the second transistor and the second node; and
a second pull-down transistor that is gated by the voltage of the first node, is connected to the second pull-up transistor, and pulls down the voltage of the second node, based on the voltage of the first node.

16. The image sensor of claim 15, wherein a time when the second pull-up transistor is turned on and a time when the second pull-down transistor is turned on change based on a size of the second pull-down transistor.

17. An image sensor comprising:
a pixel array comprising one or more pixels;
a row driver outputting a control signal for controlling an operation of the one or more pixels;
an analog-to-digital converter converting a pixel signal that is output from the one or more pixels via a column line, into a digital signal, and outputting the digital signal; and
a timing generator generating a clock signal, and transmitting the clock signal to the row driver and the analog-to-digital converter,
wherein the row driver comprises:
a shifting circuit comprising two inverters that are cross-coupled and output a target voltage;
a source circuit comprising a current source that is connected to a source node, and a source transistor that is gated by a voltage of the source node;
a sub-circuit that is gated by the voltage of the source node, and provides the target voltage to the shifting circuit, based on the voltage of the source node; and
an enable circuit receiving an enable signal, and enables the shifting circuit based on the enable signal.

18. The image sensor of claim 17, wherein the shifting circuit further comprises a first node and a second node, and shifts a voltage of the first node from a first voltage to a second voltage and a voltage of the second node from the second voltage to the first voltage, using the two inverters.

19. The image sensor of claim 18, wherein the enable circuit further comprises an enable transistor that is gated by the enable signal, and pulls down the voltage of the first node, based on the enable signal.

20. The image sensor of claim 18, wherein the sub-circuit comprises:
a first transistor providing the target voltage to the first node; and
a second transistor providing the target voltage to the second node.
